(19) United States
(12) Patent Application Publication
(10) Pub. No.: US 2009/0167355 A1
(43) Pub. Date: Jul. 2, 2009

(54) High performance pulsed buffer

(76) Inventor: Patrick Bosshart, Plano, TX (US)

Correspondence Address: TEXAS INSTRUMENTS INCORPORATED, P O BOX 655474, M/S 3999, DALLAS, TX, 75265, US

(21) Appl. No.: 11/967,837

(22) Filed: Dec. 31, 2007

(51) Int. Cl. H03K 19/0175

(52) U.S. Cl. 326/62

(57) ABSTRACT

An integrated circuit (200) includes a pulsed buffer (226) having dynamic logic. The dynamic logic includes a first input device (215) coupled to receive a data input signal, a first dynamic node (222), and a first pull up device (224) which when conducting couples the first dynamic node (222) to a positive voltage supply. A first (234) and a second pull down device (238) are connected between the dynamic node (222) and a negative supply operable to discharge the dynamic node (222) when the first input device (215) and both the first and second pull down devices (238, 234) are on. The first pull down device (234) is connected to a first clock signal (CLK), and the second pull down device (238) is coupled to an inverted second clock signal having an odd number of signal inversions being >3 inversions, such as 3 inversions (CLKXXX), relative to the first clock signal (CLK).

### TECHNICAL FIELD OF THE INVENTION

The present invention relates generally to integrated circuits including pulsed buffers.

### BACKGROUND OF THE INVENTION

Two common circuit functions for buffer circuits are clock gating and handing off signals from static to dynamic logic. As described below, these functions become difficult when operating at very high clock frequencies, where the flow through delay of a register is most of the clock cycle, leaving little time for other functions.

Dynamic logic (or clocked logic) is distinguished from so-called static logic in that it uses a clock signal in its implementation of combinational logic. A popular implementation of dynamic logic is domino logic. Domino logic is a precharged, non-inverting family of Complementary Metal Oxide Silicon (CMOS) logic that uses multiple clock phases to effect high-speed operation. Typically in domino logic, at least a “precharge” clock phase is used, followed by an “evaluate” clock phase. During the precharge phase, when the clock is low, the output of the cell goes low. During the evaluate phase, when the clock is high, the output of the cell can only transition from a low to a high value.

FIG. 1 shows an integrated circuit 100 including a conventional clock gator buffer circuit configuration 102 comprising a latch 110 coupled to domino logic 115, operating off an enable signal EN from a register 105. The data input to register 105 is shown as the signal D. Delays as described herein will be simply counted as numbers of inversions. The EN signal changes on the rising edge of the twice inversion delayed clock CLKXX. Latch 110 is transparent when the clock is low, so its output signal EN_L changes on the falling edge of is thrice inversion delayed clock CLKXXX and remains stable all the time the clock is high. EN_L gates the clock through the subsequent domino gate 115, which is shown comprising NAND gate 116 coupled to inverter 117, thus implementing the AND function. The purpose of latch 110 is to ensure EN_L is stable during clock high, so there are no clock slivers at the output of the clock gator 102, the gated clock output of the clock gator 102 shown as GLCK, such as when the EN signal from the register 105 changes on the rising edge of CLKXX.

An examination of the delays of conventional clock gator buffer circuit 102 will provide some insight concerning why conventional clock gator buffer circuit 102 may become inoperable or poorly performing at high frequencies. For the purposes of this example, the gated clock output GCLK is intended to have the same delay (2 inversion delays) as the input clk CLKXX to latch L2 of register 105. Accordingly, the two inversion delays of the NAND 116 and inverter 117 in domino gate 115 match against the two inversion delays of CLKXX.

As described above, from the CLK signal, it takes two inversion delays to produce CLKXX. It is presumed that the CLK to q (output) delay of latch L2 of register 105 is two inversion delays, and the flowthrough delay of latch 110 is also two inversion delays. That is thus a total of 6 inversion delays from CLK to EN_L. The minimum clock period at which conventional clock gator buffer 102 will operate is the sum of those 6 inversion delays, with the clock period getting longer if any other circuitry is added into the circuit path.

An examination of the time constraints on the clock low portion of the period shows a worse timing path. From CLK falling, there are three inversions delays to the clock input of latch 110 and two more inversions in its clock (e.g. CLKXXX) to q path. So half the clock cycle must be 5 inversions long, or equivalently, the cycle must be roughly 10 inversions long. If instead of the connection shown in FIG. 1, latch L3's pre-inverter clock input is connected to CLK rather than CLKXX, saving two inversions, the clock high time becomes the problem phase, with similar adverse results.

The problem becomes even worse if the clock gator 102 has to produce an early clock making the clock of the domino gate 115 move to an even earlier clock. This approach directly subtracts from the setup time available and adds to the clock phase duration.

The domino gate's extra input relative to static logic gates is connected to a clock, and is generally AND'ed with all other inputs. Referring again to FIG. 1, the NAND 116 plus inverter 117 in the clock gator 102 is equivalent to a simple domino gate with CLK as the clock input, and EN_L as the single logic input. Of course, more complex domino gates could have more inputs than just EN_L, and combine them into a more complex logic function. As noted above, clock gator buffer 102 includes latch L3/110 which operates as an interface/handoff circuit where a static signal EN received by latch L3/110 is used to drive domino gate 115. Such interface/handoff circuits are generally required in conventional circuits whenever a portion of a circuit is implemented in static logic (e.g. AND, OR, etc.), another portion in clocked logic (e.g. domino logic), and the phase of the static logic signal is not directly compatible with the clocked logic.

The conventional clock gator buffer circuit 102 shown in FIG. 1 described above illustrates that conventional buffer circuits have problems when the clock period is reduced to the point that the latch delays become a substantial fraction of the clock cycle. What is needed is an improved buffer design that passes signals from static logic to dynamic logic (e.g. domino logic) with less delay, thus allowing operation at higher frequencies.

### SUMMARY

This Summary is provided to comply with 37 C.F.R. §1.73, requiring a summary of the invention briefly indicating the nature and substance of the invention. It is submitted with the understanding that it will not be used to interpret or limit the scope or meaning of the claims.

An integrated circuit comprises a pulsed buffer including dynamic logic, such as domino logic. The dynamic logic includes a first input device coupled to receive a data input signal, a first dynamic node, and a first pull up device which when conducting couples the first dynamic node to a positive voltage supply. A first and a second pull down device connected in series with respect to the dynamic node and a negative supply (or ground) is operable to discharge the dynamic node when the first input device and both the first and second pull down devices are on. The first pull down device is connected to a first clock signal, and the second pull down device is coupled to a second clock signal having an odd number of signal inversions being >3 inversions (e.g. 3 inversions), relative to the first clock signal. A dual rail pulse buffer is also described.

### BRIEF DESCRIPTION OF THE DRAWINGS

FIG. 1 shows an integrated circuit including a conventional clock gator buffer circuit configuration comprising a latch operating as an interface/handoff circuit coupled to domino logic.

FIG. 2A shows an integrated circuit including a register, and a single rail pulsed buffer comprising a dynamic gate, and clock interface circuitry according to an embodiment of the invention.

FIG. 2B shows an integrated circuit including a register, a dual rail pulsed buffer, and clock interface circuitry according to another embodiment of the invention.

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention.

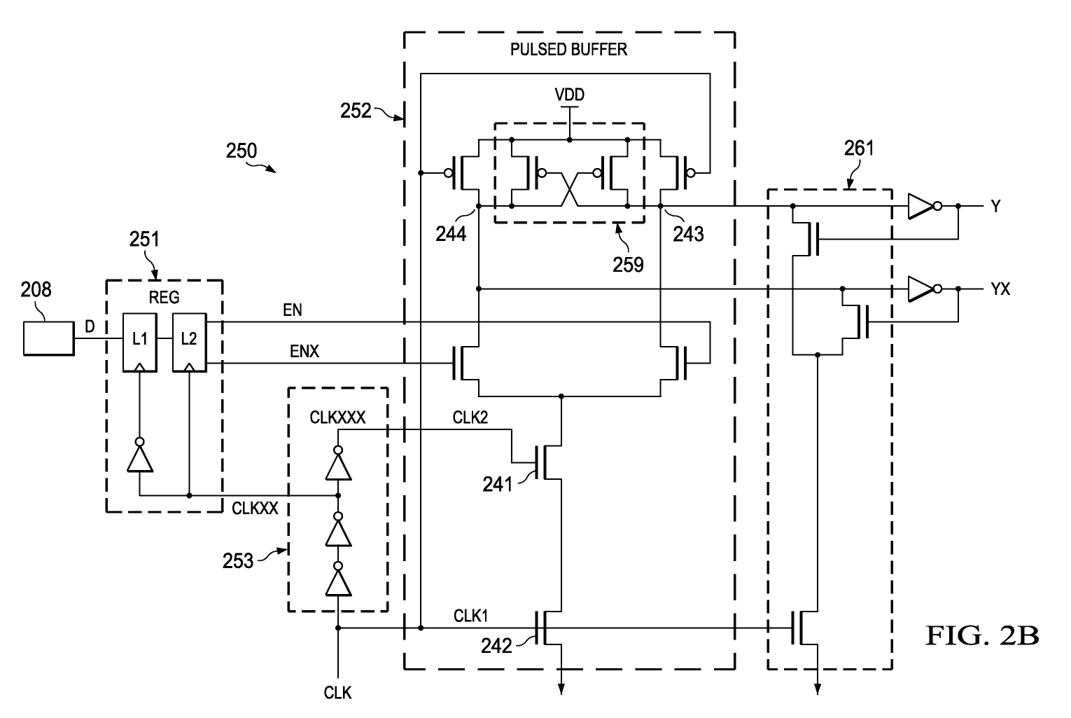

FIG. 2A shows an integrated circuit 200 including a register 201, a single rail pulsed buffer 202, and clock interface circuitry 203 according to an embodiment of the invention. The data (D) input to register 201 can be provided by a static logic circuit 208. Clocked interface circuitry 203 comprises three serially connected inverters. Pulsed buffer 202 can be realized using dynamic logic, such as the CMOS domino logic shown. Logic 215 generally comprises NMOS transistors and can also include PMOS, which as shown receives a single data input (En). However, logic 215 can receive a plurality of data inputs, such as one input per transistor, for example a four-input CMOS domino circuit in a cascade configuration with corresponding four input transistors. In the case of NMOS, when a logic high is applied to the gate of input logic transistor(s), the associated input transistor is turned on.

An output indication of the conduction of all transistors in logic can be determined at dynamic node 222. Dynamic node 222 is also connected to a PMOS pull up (precharge) transistor 224 which has its source connected to a supply voltage Vdd. When transistor 224 is driven into conduction, such as by a logic low voltage on its gate input 226 by CLK, the supply voltage (Vdd) is coupled through transistor 224 and is applied to dynamic node 222. The node is thus precharged to a logic high voltage. According to the conventional operation of MOS circuits, when transistor 224 is turned off, the node 222 will remain precharged to the supply voltage until the transistor(s) comprising logic 215 provides a conductive path from dynamic node 222 to node 223. In the case of cascaded transistors comprising logic 215, each transistor is driven into conduction. An inverter 228 is connected between node 222 and the output of the domino circuit for providing the complement of the signal appearing at node 222 to the next stage.

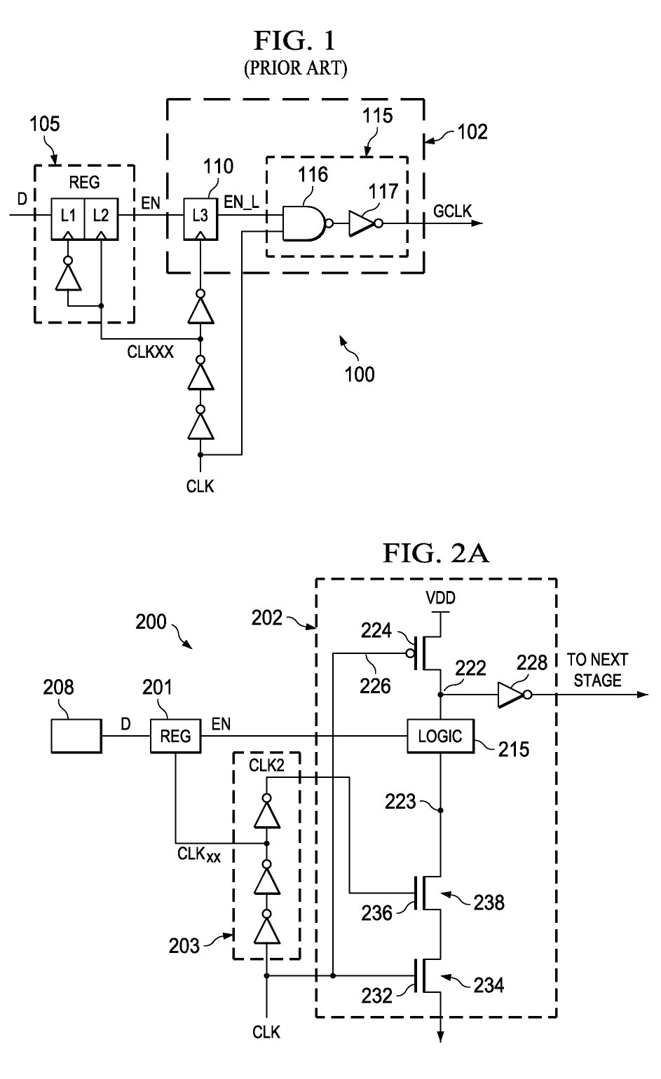

In contrast to conventional pulldown configurations that utilize a single pulldown transistor, pulsed buffer 202 comprises an upper NMOS pull down transistor 238 and a lower NMOS pull down transistor 234. In operation of the pulsed buffer 202, a clock input signal CLK is connected to the gate 226 of transistor 224, as well as to the gate 232 of the lower NMOS pull down transistor 234. The drain of lower pull down transistor 234 is connected to the source of upper pull down transistor 238. The gate 236 of upper pull down transistor 238 is shown receiving a three signal inversion delayed CLK signal. The source of transistor 234 is connected to ground. In operation, when a logic high is applied to gates 232 and 236, discharge transistors 234 and 238 are both driven into conduction, thereby grounding the lower connection to logic 215 (e.g. a source of an input transistor). Thus, the additional 3 inversion delayed clock signal CLK2 and upper pulldown transistor 238 replaces the latch L3/110 shown in FIG. 1, and provides reduced delay and thus allows higher frequency operation for pulsed buffer 202 as compared to clocked gator 102.

Although the delayed clock signal is shown coupled to the gate 236 of the upper NMOS discharge transistor 238 and the clock signal (without relative delay) coupled to the gate 232 of lower pull down transistor 234, as will be clear to those having ordinary skill in the art, the respective clock signal connections can be reversed (e.g. delayed clock signal to pull down discharge transistor 234 and clock signal (without relative delay) coupled to upper pull down transistor 238.

As known in the art, some circuits cannot be implemented solely using dynamic logic, such as domino logic, unless both polarities (true and complement) of the inputs are available. If both polarities of inputs arc available then both polarities of internal signals can be generated by two dynamic gates, such as domino gates, connected in parallel so subsequent stages will have both polarities of their inputs available. FIG. 2B shows an integrated circuit 250 including a register 251, a dual rail pulsed buffer 252, and clock interface circuitry 253, according to an embodiment of the invention. Pulsed buffer 252 like pulsed buffer 202 described above provides reduced delay and thus allows high frequency operation as compared to conventional clocked gator 102 shown in FIG. 1 by eliminating latch L3/110.

The input signal D is shown in FIG. 2B registered by register 251, comprising latches L1 and L2. Although register 251 is shown comprising two latches, only the rightmost latch L2 is generally required to provide its timing function. Register 251 is operable to output the enable signal EN, and also its complement shown as ENX. Latch L2 in register 251 is clocked with CLKXX which is tapped off the second inverter of the series connected three inverters provided by clock circuitry 253, while latch L1 is clocked with CLK having three signal inversions of delay. Pulsed buffer 252 is shown comprising a domino logic circuit and includes an additional clock input CLK2 connected to an additional second (upper) pulldown transistor 241 in the pulldown stack in series with lower pulldown transistor 242. As with circuit 200, this additional clock signal CLK2 and pulldown transistor 241 replaces latch 110 shown in FIG. 1, and provides reduced delay and thus allows higher frequency operation for pulsed buffer 252 as compared to clocked gator 102. Moreover, as described above relative to circuit 200, the clock connections relative to the respective discharge transistors 241 and 242 can be reversed.

As described above, latch 110's sole function in clocked gator 102 shown in FIG. 1 is to avoid incorrect clock gating (e.g. output slivers) when the EN signal from the register 105 are changed on the rising edge of CLKXX. This function is provided by storing the old data value before the clock rising edge. In contrast, for pulsed buffer 252 shown in FIG. 2B, the second clock input CLK2 is connected to the inverted and delayed elk CLKXXX, which in this example has a three signal inversions of delay relative to the input signal CLK. Therefore, when CLK rises, CLKXXX remains high for three signal inversions of delay, allowing the domino logic in pulsed buffer 252 to operate, and one or the other of the dynamic nodes of the domino logic shown as nodes 243 and 244 to discharge. After the three signal inversions of delay, CLKXXX falls to a low logic (e.g. zero) value, shutting off device 241 thus cutting off the discharge path of domino logic gate to ground, so thereafter the domino gate will not respond to changes in the values of the enable signals EN and ENX provided by register 251. Accordingly, the hold time requirement at the pulsed buffer 252 is the three signal inversion delayed from CLK rising to CLKXXX falling, whereas the delay time before new values arrive at EN and ENX is four signal inversions: two to CLKXX and two more in the clock to q (data out) delay of the register 251.

Pulsed buffer 252 is shown including optional dual rail keeper circuit 259 embodied as cross coupled PFETs connected between the first and second dynamic nodes 243 and 244. Dual rail keeper circuit 259 serves as keepers for the dynamic nodes 243 and 244 and thus makes the domino gate effectively static. Other first keeper circuit embodiments may also be used with embodiments of the invention.

Pulsed buffer 250 is also shown including a second keeper circuit 261, which comprises a first and a second NMOS transistor having their respective gates coupled to outputs Y and YX, and their sources connected to the respective dynamic nodes 244 and 243. Other second keeper circuit embodiments may also be used with embodiments of the invention.

An examination of the clock cycle constraint shows significantly improved operation for pulsed buffer 252 in comparison to the conventional pulse buffer circuit 102 shown in FIG. 1. For circuit 250 shown in FIG. 2B, when CLK rises, the pulsed buffer 252 input signals EN and ENX have a four signal inversion of delay to arrive at the pulsed buffer 252 before the next rising edge of CLK. Without the latch L3/110 of FIG. 1 for pulsed buffer 252 shown in FIG. 2B, there are no half cycle constraints other than those pulse widths needed to permit register 251 and pulsed buffer 252 to operate. So in comparison to the 10 inversion delay clock cycle for circuit 100 shown in FIG. 1 described above, there are no path constraints for circuit 250 with more than 4 signal inversions. To the extent that the clock cycle in a circuit design is longer than those 4 signal inversion delays, such delay provides time to implement additional static logic functions in the path from the register/flop 251 to the input of the pulsed buffer 252.

Pulsed buffers according to the invention can be used in a variety of circuits whenever a portion of a circuit is implemented in static logic, another portion in clocked logic, and the phase of the static logic signal is not directly compatible with the clocked logic. For example, in one exemplary application, pulsed buffers according to an embodiment of the invention are used to pass signals from static logic to dynamic (e.g. domino) logic at high frequencies due to the significantly reduced signal delay provided.

Although not shown, embodiments of the invention are applicable to multiple-output functions beyond complementary outputs. In addition, the invention may be implemented with negative logic, such as by inverting the transistor types and the supply rails. Moreover, although a CMOS based pulsed buffer has been discussed in accordance with the present invention, it is appreciated by the Inventor that other transistor technology variations, may generally be used. In addition, devices other than buffers are contemplated in the context of the present invention. The invention is also not limited to the use of silicon wafers, and may be implemented in association with the manufacture of various semiconductor devices. Moreover, the respective clock signals analogous to CLK and the second clock signal having an odd number of signal inversions being >3 signal inversions relative to CLK (e.g. CLKXXX described above) may be provided by other circuit arrangements, such as by a pair of suitably phased dynamic gates.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including,” “includes,” “having,” “has,” “with,” or variants thereof are used in either the detailed description and/or the claims, such terms are intended to be inclusive in a manner similar to the term “comprising.”

The Abstract of the Disclosure is provided to comply with 37 C.F.R. §1.72 (b), requiring an abstract that will allow the reader to quickly ascertain the nature of the technical disclosure. It is submitted with the understanding that it will not be used to interpret or limit the scope or meaning of the following claims.

1. An integrated circuit, comprising:
a pulsed buffer comprising dynamic logic, including:
a first input device coupled to receive a data input signal;
a first dynamic node;
a first pull up device which when conducting couples said first dynamic node to a positive voltage supply, and
a first and a second pull down device connected between said dynamic node and a negative supply operable to discharge said dynamic node when said first input device and both said first and second pull down devices are on,
wherein said first pull down device is connected to a first clock signal, and said second pull down device is coupled to a second clock signal having an odd number of signal inversions being >3 signal inversions relative to said first clock signal.

2. The integrated circuit of claim 1, wherein said dynamic logic comprises domino logic.

3. The integrated circuit of claim 1, further comprising a register or at least one latch coupled to a gate of said first input device for providing said data input signal.

4. The integrated circuit of claim 3, further comprising a static logic circuit having its output coupled to said register or said latch.

5. The integrated circuit of claim 1, wherein a clock for said register or said latch is two signal inversions delayed relative to said first clock signal.

6. The integrated circuit of claim 1, further comprising an inverter having an input coupled to said dynamic node.

7. An integrated circuit, comprising:
a pulsed buffer comprising dynamic logic, including:
a first and a second input device coupled to receive a data signal and its complement, respectively;
a first and a second dynamic node;
a first and a second pull up device which when conducting respectively couple said first and said second dynamic node to a positive voltage supply, said first and second dynamic nodes coupled to first and second output inverters, respectively, and
a first and second pull down device connected between said dynamic codes and a negative supply operable to discharge said first dynamic node when both said pull down devices are on along with said first input device, and operable to discharge said second dynamic node when both said pull down devices are on along with said second input device, wherein said first pull down device is connected to a first clock signal, and said second pull down device is coupled to a second clock signal having an odd number of signal inversions being >3 signal inversions relative to said first clock signal.

8. The integrated circuit of claim 7, wherein said dynamic logic comprises domino logic.

9. The integrated circuit of claim 7, further comprising a register or at least one latch coupled to a gate of said first input device for providing said data input signal and said complement of said data signal.

10. The integrated circuit of claim 7, further comprising a static logic circuit having its output coupled to said register or said latch.

11. The integrated circuit of claim 7, wherein a clock signal for said register or said latch is two signal inversions delayed relative to said first clock signal.

12. The integrated circuit of claim 7, wherein said first and second input device comprise a common source connected first and second NMOS transistor connected between said first dynamic node and said pull down devices and said second dynamic node and said pull down devices, respectively.

13. The integrated circuit of claim 7, further comprising a dual rail keeper circuit connected between said positive power supply and said first and said second dynamic nodes.

14. A method of buffering data signals between static logic and dynamic logic, said dynamic logic having a first and a second series connected pull down transistor stack connected between at least one dynamic node and a low power supply, comprising:
providing a first clock signal and a second clock signal having an odd number >3 of signal inversions relative to said first clock signal;
coupling said first clock signal to a gate of said first pull down transistor and said second clock signal to said second pull down transistor; wherein when said first clock rises, said second clock remains high for said an odd number >3 of signal inversions of delay allowing said dynamic logic to operate and said at least one dynamic node to discharge.

15. The method of claim 14, wherein said at least one dynamic node comprises a first and a second dynamic node.

16. The method of claim 14, wherein a latch or register is interposed between said logic circuit and said dynamic logic, further wherein a clock signal for said register or said latch is two signal inversions delayed relative to said first clock signal.

17. The method of claim 14, wherein said dynamic logic comprises domino logic.
